(19) United States
(12) Patent Application Publication
(10) Pub. No.: US 2025/0053703 A1
(43) Pub. Date: Feb. 13, 2025

(54) SYSTEM AND METHODS FOR GENERATING MULTI-DIMENSIONAL MODELS AND REPORTS

(71) Applicant: Inversion Solutions LLC, Charlotte, NC (US)

(72) Inventor: Zack Raboin, Charlotte, NC (US)

(21) Appl. No.: 18/446,952

(22) Filed: Aug. 9, 2023

(51) Int. Cl. G06F 30/23; G06V 10/25

(52) U.S. Cl. CPC G06F 30/23; G06F 30/10; G06F 30/13; G06V 10/25; G06F 30/18

(57) ABSTRACT

A system comprising at least one computing device in communication with a data store configured to: receive first capture data from at least one sensor, the first captured data relating to a first fixture within a particular area of interest. Receive second capture data from the at least one sensor, the second captured data relating to a second fixture within the particular area of interest. Determine a plurality of first characteristics and second characteristics for the first fixture and second fixture based on the first capture data and second capture data, respectively. Receive metadata associated with a subset of the particular area of interest from a second data source; and generate a multi-dimensional model of the particular area of interest comprising the first fixture based on the plurality of first characteristics, the second fixture based on the plurality of second characteristics, and at least one indicator based on the metadata.

### TECHNICAL FIELD

The present disclosure relates generally to systems and methods for aggregating and processing data associated with construction sites to generate multi-dimensional models and various reports.

### BACKGROUND

Infrastructure and construction are vital components of a functional economy. Ranging from utility services to federal roadwork, upkeep of current systems and the addition of new projects are constant endeavors performed within these industries. When embarking on a new infrastructure and/or construction project, planning and progress management are essential steps that cannot be overlooked. For example, effective tracking of financial progress can drastically impact the speed and quality of the job's final outcome. In another example, proper field surveying and reconnaissance prior to commencing a job can lay the ground work for accurately completing the tasks at hand.

Traditional systems and methods used to perform these tasks lack the technological sophistication granted by the tools of the twenty-first century. For example, typical reconnaissance for a new high-speed internet infrastructure is performed by field technicians that are potentially ill prepared or lack the necessary tools for effectively gathering pertinent data. Additionally, the systems in place to track the progress of a project are disparate and lack the necessary insight to maximize the efficiency of the particular team completing the project. A combination of poor data collection and ineffective data utilization has plagued the infrastructure and construction industries with inaccurate completion estimates, over budget projects, and poorly finished developments.

Therefore, there is a long-felt but unresolved need for a system or method that aggregates data from disparate data sources, processes the data to generate insights associated with the particular construction project, and renders the processed data through a multi-dimensional model and/or one or more reports using various visual, mathematical, and/or written aids.

### BRIEF SUMMARY OF THE DISCLOSURE

Briefly described, and according to one embodiment, aspects of the present disclosure generally relate to systems and methods for aggregating data associated with a particular construction project from disparate data sources, processing the data to generate insights associated with the particular construction project, and rendering processed data through a multi-dimensional model and/or one or more reports using various visual, mathematical, and/or written aids.

The disclosed innovation can include a construction analysis system used to aggregate, process, and generate insights associated with a utility service construction project. The utility service construction project can be any particular project performed for the purpose of improving, adding, removing, remodeling, and/or otherwise changing current utility infrastructures. For example, the utility service construction project can include a proposed installation of a fiber-optic internet system along a 15 mile road in a neighborhood. Although discussed in the context of utility providers, the construction analysis system can be applied to non-utility related construction projects.

The construction analysis system can include various systems communicating across a network. For example, the construction analysis system can include a computing environment, one or more computing devices, one or more data sources, and a reporting device. The one or more computing devices can be deployed at the location of the utility service construction project to gather data associated with various characteristics of the utility service construction project. The computing environment can function as the centralized computing source of the construction analysis system. For example, the computing environment can include a server and processing system for aggregating data, processing data, and generating multi-dimensional models and/or reports associated with the aggregated data. The computing environment can process data from the one or more computing devices to identify characteristics associated with the utility service construction project.

The computing environment can request third party data from the data sources. Based on the type of utility service construction project, the computing environment can request data from various third party resources to augment the analysis associated with the gathered data and the utility service construction project. The computing environment can generate a multi-dimensional model of the utility service construction project. The multi-dimensional model of the utility service construction project can include but is not limited to a satellite map view, an orthomosaic map, a multi layered map, indicators, photo simulations, comments, financial indicators, augmented reality visual aids, and various metrics. The computing environment can generate reports associated with the utility service construction project. For example, the computing environment can generate Gantt charts, timing charts, and/or any particular project milestone reports for the utility service construction project. The computing environment can distribute the multi-dimensional models and the one or more reports to the reporting device. The reporting device can render the multi-dimensional models and the one or more reports on the display.

These and other aspects, features, and benefits of the claimed embodiments will become apparent from the following detailed written description of embodiments and aspects taken in conjunction with the following drawings, although variations and modifications thereto may be effected without departing from the spirit and scope of the novel concepts of the disclosure.

### BRIEF DESCRIPTION OF THE DRAWINGS

The accompanying drawings illustrate one or more embodiments and/or aspects of the disclosure and, together with the written description, serve to explain the principles of the disclosure. Wherever possible, the same reference numbers are used throughout the drawings to refer to the same or like elements of an embodiment, and wherein:

FIG. 1 illustrates a construction analysis system, according to one embodiment of the present disclosure;

FIG. 2 illustrates a flowchart of a process, according to one embodiment of the present disclosure;

FIG. 3 illustrates a flowchart of a process, according to one embodiment of the present disclosure;

FIG. 4 illustrates a flowchart of a process, according to one embodiment of the present disclosure; and

FIG. 5 illustrates a flowchart of a process, according to one embodiment of the present disclosure.

### DETAILED DESCRIPTION

For the purpose of promoting an understanding of the principles of the present disclosure, reference will now be made to the embodiments illustrated in the drawings and specific language will be used to describe the same. It will, nevertheless, be understood that no limitation of the scope of the disclosure is thereby intended; any alterations and further modifications of the described or illustrated embodiments and any further applications of the principles of the disclosure as illustrated therein are contemplated as would normally occur to one skilled in the art to which the disclosure relates. All limitations of scope should be determined in accordance with and as expressed in the claims.

Whether a term is capitalized is not considered definitive or limiting of the meaning of a term. As used in this document, a capitalized term shall have the same meaning as an uncapitalized term, unless the context of the usage specifically indicates that a more restrictive meaning for the capitalized term is intended. However, the capitalization or lack thereof within the remainder of this document is not intended to be necessarily limiting unless the context clearly indicates that such limitation is intended.

### Overview

Aspects of the present disclosure generally relate to systems and methods for aggregating data associated with a particular construction project from disparate data sources, processing the aggregated data to generate insights associated with the particular construction project, and rendering the processed data through a multi-dimensional model and/or one or more reports using various visual, mathematical, and/or written aids. The disclosed innovation can include a construction analysis system used to aggregate, process, and generate insights associated with a utility service construction project. The utility service construction project can be any particular project performed for the purpose of improving, adding, removing, remodeling, and/or otherwise changing current utility infrastructures. For example, the utility service construction project can include a proposed installation of a fiber-optic internet system along a 15 mile road in a neighborhood. In another example, the utility service construction project can include a proposed instillation for power lines in a new neighborhood. Although discussed in the context of utility providers, the construction analysis system can be applied to non-utility related construction projects. For example, the construction analysis system can facilitate project management and analysis for a sidewalk construction project. In another example, the construction analysis system can facilitate project management and analysis for a bridge construction project.

The construction analysis system can include various systems communicating across a network. For example, the construction analysis system can include a computing environment, one or more computing devices, data sources, and a reporting device. Throughout the various phases of the utility service construction project, the construction analysis system can employ the computing environment, the one or more computing devices, and the data sources to aggregate and process data.

The utility service construction process can begin by gathering data. The one or more computing devices can be deployed at the location of the utility service construction project to gather data associated with various characteristics of the utility service construction project. For example, one computing device can include a drone system used to take aerial photographs of the landscape and topography where the utility service construction project will take place. In another example, one computing device can include a data capture device used to gather location data, LiDAR data, camera data, and/or any other data associated with the location of the utility service construction project. The one or more computing devices can be combined to form a singular data aggregation tool capable of gathering any particular data type.

Once the data has been aggregated, the computing environment can receive the data from the one or more computing devices. The computing environment can function as the centralized computing source of the construction analysis system. For example, the computing environment can include a server and processing system for aggregating data, processing data, and generating multi-dimensional models and/or reports associated with the aggregated data. The computing environment can process data from the one or more computing devices to identify characteristics associated with the utility service construction project. For example, the computing environment can identify fixtures throughout a series of photos and videos recorded by the data capture device. The fixtures can represent any infrastructure component utilized in the utility service construction project. For example, the fixtures can include one or more utility poles distributed throughout the utility service construction project used to support wires and other electronic components above ground. In the discussion herein, the fixtures can be defined as one or more utility poles used to support electronic equipment at various heights above the ground.

The computing environment can request third party data from the data sources. Based on the type of utility service construction project, the computing environment can request data from various third party resources to augment the analysis associated with the gathered data and the utility service construction project. The data sources can include, but are not limited to USPS public data, Google Maps Satellite data, FCC data, private data sources, public data sources, financial data, distributor data, construction related data, and/or any other pertinent data source.

The computing environment can generate a multi-dimensional model of the utility service construction project. The multi-dimensional model of the utility service construction project can include but is not limited to a satellite map view, an orthomosaic map, a multi layered map, indicators, photo simulations, comments, financial indicators, augmented reality visual aids, and various metrics. The computing environment can generate reports associated with the utility service construction project. For example, the computing environment can generate Gantt charts, timing charts, and/or any particular project milestone reports for the utility service construction project. In another example, the computing environment can generate engineering drawings and/or any particular drawings for the utility service construction project. In yet another example, the computing environment generates invoices, budget updates, and/or any particular financial report associated with the utility service construction project. The computing environment can distribute the multi-dimensional models and the one or more reports to the reporting device. The reporting device can render the multi-dimensional models and the one or more reports on the display.

### Exemplary Embodiments

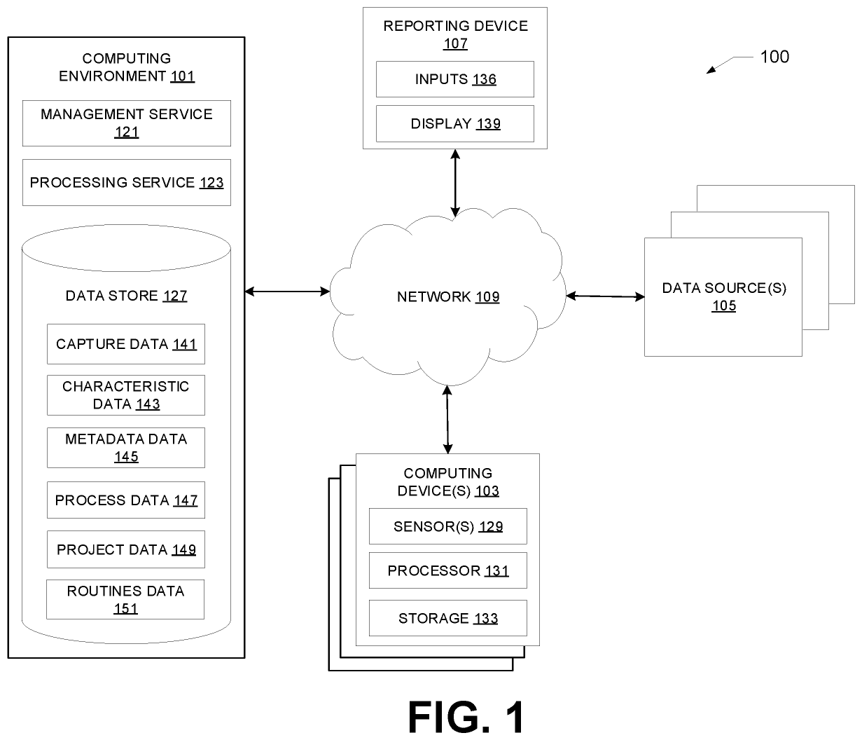

Referring now to the figures, for the purposes of example and explanation of the fundamental processes and components of the disclosed systems, reference is made to FIG. 1, which illustrates a construction analysis system 100. As will be understood and appreciated, the construction analysis system 100 shown in FIG. 1 represents merely one approach or embodiment of the present system, and other aspects are used according to various embodiments of the present system.

The construction analysis system 100 can be a networked environment used to aggregate and process various data associated with a utility service construction project. The utility service construction project can be defined as any particular project performed for the purpose of improving, adding, removing, remodeling, and/or otherwise changing current utility infrastructures. For example, a utility service construction project can include an installation of various small cell environments in an area of 30 square miles. In another example, the utility service construction project can include a proposed installation of a fiber-optic internet system along a 15 mile road in a neighborhood. In yet another example, the utility service construction project can include a proposed instillation for power lines in a new neighborhood. The construction analysis system 100 can be applied to any construction project outside of the utilities industry. For example, the construction analysis system 100 can be applied to any government infrastructure project (e.g., road projects, sidewalk projects, bridge projects), commercial project (e.g., office space constructions, single family home construction, multi-family home construction), and/or any other particular non-utility construction project. For example, all data collection and data analysis techniques associated with the utility service construction project performed by the construction analysis system 100 can equally be performed on any construction project. The construction analysis system 100 can aggregate data from various resources distributed across a network 109. The construction analysis system 100 can generate one or more multi-dimensional models and/or various reports associated with the various data and the utility service construction project. The potential functionality of the various components of the construction analysis system 100 will be discussed in further detail herein.

The construction analysis system 100 can include a computing environment 101, one or more computing devices 103, one or more data sources 105, and a reporting device 107. The computing environment 101, the computing devices 103, the data sources 105, and the reporting device 107 can be in data communication with each other via a network 109. The network 109 can include, for example, the Internet, intranets, extranets, wide area networks (WANs), local area networks (LANs), wired networks, wireless networks, or other suitable networks, etc., or any combination of two or more such networks. For example, such networks can include satellite networks, cable networks, Ethernet networks, Bluetooth networks, Wi-Fi networks, NFC networks, and other types of networks.

The computing devices 103 can be any particular device used to gather data at the site of the utility service construction project. The computing devices 103 can include a drone, a data capture device, a mobile cellphone, a tablet, and/or any other computing system that can record data. For example, the computing devices 103 can use the drone to gather aerial and atmospheric data. In another example, the computing devices 103 can use the data capture device for gathering topographical data and images at the site of the utility service construction project. In yet another example, the computing device 103 can use the mobile cellphone with a data recording application installed to gather data associated with the utility service construction project. The computing devices 103 can include, for example, a processor-based system such as a computer system. Such a computer system can be embodied in the form of a desktop computer, a laptop computer, personal digital assistants, cellular telephones, smartphones, web pads, tablet computer systems, or other devices with like capabilities.

Each of the one or more computing devices 103 can include one or more sensors 129, a processor 131, and a storage 133. The sensors 129 can be any particular sensor used to gather capture data 141 on the site of the utility service construction project. The sensors can include but are not limited to cameras, microphones, barometer, temperature sensors, LiDAR sensors, elevation sensors, global positioning system (GPS) sensors, humidity sensors, distance sensors, internal gyroscopes, accelerometers, compasses, and any/other particular sensor. For example, the one or more drones can be equipped with sensors including cameras, LiDAR sensors, and GPS sensors to form a three dimensional topographical map of the surface of the utility service construction project.

The processor 131 can function as a local computing source for the computing devices 103. The processor 131 can be any particular processing unit capable of functioning as a computing system. For example, the processor 131 can include a central processing unit (CPU), a graphics processing unit (GPU), a microcontroller system, a microprocessor system, a memory system, a communication system, an input/output system, or any combination thereof. The processor 131 can work simultaneously with the computing environment 101. For example, the computing environment 101 can employ the processor 131 to perform processes associated with the processing service 123. The processor 131 can send capture data 141 in real time to the computing environment 101 and/or any other system distributed across the network 109. The processor 131 can perform substantially similar functionalities to the computing environment 101.

The storage 133 can function as a local memory source for the computing devices 103. For example, the processor 131 can receive the capture data 141 from the sensors 129. Continuing this example, the processor 131 can store the capture data 141 in the storage 133. The processor 131 can access and distribute data stored in the storage 133. The storage 133 can function as an extension of the data store 127. For example, the storage 133 and the data store 127 can function as a server system distributed across the network 109. The storage 133 can include all data stored in the data store 127.

The computing devices 103 can be deployed at the site of the utility service construction project to gather reconnaissance and capture data 141. Capture data 141 can include any data gathered from the computing devices 103 and the reporting device 107. For example, during the planning phase of the utility service construction project, the computing devices 103 can be deployed at the site of the utility service construction project to gather topographical data. In another example, the mobile cellphone can employ the data recording application to record videos of one or more fixtures on a two mile road.

The one or more computing devices 103 can communicate to simultaneously gather various types of capture data 141. For example, the drone can employ the camera system to generate an aerial map while the data capture device gathers LiDAR data to augment the aerial map generated by the drone with three dimensional topographical features.

Discussed in further detail herein are the potential functionalities, use case scenarios, and features of the data capture device of the computing devices 103. The data capture device can function as a hand held device for measuring capture data 141 at the site of the utility service construction project. For example, the data capture device can be deployed by a field technician to gather various capture data 141 through the sensors 129. The data capture device can be attached to a robotic system, a vehicle, a stationary mount, and/or any particular ground based system to measure capture data 141 at the site of the utility service construction project. The sensors 129 of the data capture device can include but are not limited to a LiDAR sensor, a camera, a microphone, a barometer, a distance sensor, a temperature sensor, a humidity sensor, distance sensors, a GPS sensor, an accelerometer, a gyroscope, an electromagnetic irradiance sensor, or any combination thereof.

The data capture device can record videos and/or take images of fixtures at the site of the utility service construction project. For example, the data capture device can take a photo of existing utility poles in a subdivision. Continuing this example, the data capture device can simultaneously record LiDAR data and location data associated with each photo taken at the site of the utility service construction project. The data capture device and/or the computing environment 101 can employ the LiDAR data to determine the height and diameter of the utility poles. The data capture device can store the photos, LiDAR data, and the location data of the particular fixtures as capture data 141 in the storage 133. In another example, the data capture device can record a video of vegetation growing at the site of the utility service construction project. As the video is recorded by the camera of the data capture device, the GPS sensor can continuously record location data. Continuing this example, the processor 131 can identify the vegetation from the video and generate an indicator to highlighting the vegetation at various locations at the site of the utility service construction project based on the location data. In another example, the data capture device can gather data associated with the topography of the utility service construction project. The data capture device can employ the LiDAR sensor to form a three dimensional topographical map of the site of the utility service construction project. The data capture device can send the capture data 141 to the computing environment 101 in real time, on an automated basis, or any combination thereof.

The data capture device of the computing devices 103 can include an API service. The API service can facilitate communications between the data capture device and the computing environment 101. For example, the computing environment 101 can employ the API service to request data from the data capture device. In another example, the drone of the computing devices 103 can employ the API service of the data capture device to communicate in real time and distribute data to the data capture device. Although discussed in the context of the data capture device, any particular computing device 103 and/or the computing environment 101 can include respective API services. For example, the drone can include the API service for managing communications between the computing environment 101 and the drone. In another example, the processors 131 of each computing device 103 can run the API service of the computing environment 101 to form a communication between the computing environment 101 and/or the various other computing devices 103.

The drone of the computing devices 103 can record capture data 141 above the site of the utility service construction project. The drone can record aerial photos, aerial videos, barometric data, temperature data, wind speed data, atmospheric data, LiDAR data, and/or any particular data gatherable from a distance above the site of the utility service construction project. The sensors 129 of the drone can include but are not limited to a camera, a barometer, a LiDAR sensor, a temperature sensor, an electromagnetic irradiance sensor, any other pertinent sensor, or a combination thereof. The drone can gather data sequentially along a particular path. For example, the drone can segment a 30 square mile area for the site of the utility service construction project into 10000 individual sections. The drone can fly to each of the 10000 individual sections to gather capture data 141 associated with each particular section. By segmenting the 30 square mile area into 10000 individual sections, the drone can gather capture data 141 with greater detail as compared to a single capture data 141 of the entire area. The drone can gather capture data 141 outside of the 30 square mile area. For example, the drone can gather capture data 141 for a 50 square mile area, where the 30 square mile area of the site of the utility service construction project is included in the 50 square mile area. By gathering capture data greater than the 30 square mile area, the computing environment 101 can have a greater data set for analysis and can remove unnecessary data according to its needs.

The mobile cellphone of the computing devices 103 can gather capture data 141 at the site of the utility service construction project. The mobile cellphone can perform similar functionalities to the data capture device of the computing devices 103. The mobile cellphone can include the data recording application for gathering capture data 141. The processor 131 can run the data recording application. The data recording application can employ the sensors 129 of the mobile cellphone to gather capture data 141. The sensors 129 of the mobile cellphone can include but are not limited to a camera, a LiDAR sensor, a microphone, an accelerometer, a GPS sensor, a gyroscope, a temperature sensor, and/or any other pertinent sensor. The data recording application can employ the LiDAR sensor of the mobile cellphone to record distances and measurements associated with the fixtures at the site of the utility service construction project. For example, the camera and the LiDAR sensor of the mobile cellphone can be paired to determine the height of a particular utility pole. The mobile cellphone can include a display to render capture data 141. For example, the mobile cellphone can generate a request to confirm proper measurement of utility poles based on the capture data 141.

The reporting device 107 can function as a local computing system for one or more utility service providers. The reporting device 107 can include but is not limited to a mobile computing device, a tablet, a desktop, a laptop, and/or any particular computing system. In some embodiments, the reporting device 107 can function substantially similarly to the computing device 103, and vise-versa. For example, the mobile cellphone of the computing devices 103 can include all functionalities of the reporting device 107. The reporting device 107 can render multi-dimensional models and various other reports to the utility service provider. For example, the reporting device 107 can be a desktop at the office of the utility service provider used to render data and other pertinent information generated by the construction analysis system 100. The reporting device 139 can include a display 139 for rending multi-dimensional models and various other reports. The display 139 can include, for example, one or more devices such as liquid crystal display (LCD) displays, gas plasma-based flat panel displays, organic light emitting diode (OLED) displays, electrophoretic ink (E ink) displays, LCD projectors, or other types of display devices, etc.

The reporting device 107 can receive input data from the one or more utility service providers through one or more inputs 136. Inputs 136 can include but are not limited to a keyboard, a mouse, a touch screen, a camera, and a microphone. The reporting device 107 can received the input data, such as, site specific information associated with the utility service construction project, desired timelines for completion, financial data, utility service provider information, team contact information, and project management information. The reporting device 107 can send the input data to the computing environment 101 for storage in the data store 127 as capture data 141.

The one or more data sources 105 can include various third-party, private, public, and/or local data sources. The data sources 105 can be any particular data source that includes pre-gathered data for use during analyses associated with the utility service construction project. The data sources 105 for example, can include but are not limited to Google data sources, FCC data sources, federal regulation data sources, Environmental Systems Research Institute (ESRI) data sources, USPS data sources, jurisdictional data sources, accounting data sources, financial data sources, third-party contractor data sources, environmental data sources, historical data sources, and/or any other particular data sources including metadata 145.

The computing environment 101 can function as a centralized processing system for the construction analysis system 100. The computing environment 101 can receive data from the computing devices 103, the reporting device 107, and the data sources 105. The computing environment 101 can process the data gathered by the computing devices 103 and the reporting device 107 to generate multi-dimensional models and various other reports associated with the utility service construction project.

The computing environment 101 can include, for example, a server computer or any other system providing computing capabilities. Alternatively, the computing environment 101 can employ more than one computing devices that can be arranged, for example, in one or more server banks or computer banks or other arrangements. Such computing devices can be located in a single installation or can be distributed among many different geographical locations. For example, the computing environment 101 can include one or more computing devices that together can include a hosted computing resource, a grid computing resource, and/or any other distributed computing arrangement. In some cases, the computing environment 101 can correspond to an elastic computing resource where the allotted capacity of processing, network, storage, or other computing-related resources can vary over time.

Various applications and/or other functionality can be executed in the computing environment 101 according to various embodiments. Also, various data can be stored in the data store 127 that is accessible to the computing environment 101. The data store 127 can be representative of one or more of data stores 127 as can be appreciated. The data stored in the data store 127 for example, can be associated with the operation of the various applications and/or functional entities described below.

The data stored in the data store 127 can include, for example, lists of data and potentially other data. The data store 127 can include but is not limited to capture data 141, characteristic data 143, metadata 145, process data 147, project data 149, and routines data 151. The data store 127 can include all data associated with the utility service construction project.

The capture data 141 can include any data measured, recorded, processed, and/or generated by the computing devices 103. The capture data 141 can be associated with one or more utility service construction projects. The capture data 141 can include but is not limited to temperature data, pressure data, wind speed data, GPS data, solar irradiance data, videos, photos, LiDAR data, electromagnetic radiation data, topographical data, vegetation data, humidity data, and/or any other measurable data from the site of the utility service construction project. The computing environment 101 can receive the capture data 141 in real time from the one or more computing devices 103. The computing environment 101 can perform time based data requests from the computing devices 103. For example, the computing environment 101 can request data from the computing devices 103 at a specific time daily, monthly, and/or yearly. In another example, the computing environment 101 can request data from the computing devices 103 in response to the computing environment 101 detecting the computing devices 103 connecting with the network 109. The management service 121 can store the data received from the one or more computing devices 103 in the data store 127.

The capture data 141 can include the input data received through the reporting device 107. The input data from the reporting device 107 can include but is not limited to site specific information (e.g., address, site size, site owners), date specific information (e.g., project completion deadlines, projected start of construction, intermediate check-in dates), project management information (e.g., departments working on the utility service construction project, contractor names, contractor addresses, financial data), and/or any other data input by the utility service provider through the reporting device 107.

The characteristic data 143 can include any features extracted by the processing service 123 form the capture data 141. Characteristic data 143 can include but is not limited to photo sizing characteristics, atmospheric characteristics, weather characteristics, location characteristics, project specific mapping characteristics, and construction characteristics. The characteristic data 143 can be generated in relationship to one or more fixtures analyzed by the computing devices 103. For example, the capture data 141 recorded by the one or more computing devices 103 can be specific to a particular fixture at the site of the utility service construction project. The characteristic data 143 can include data associated with one or more utility poles at the site of the utility service construction project. For example, the processing service 123 can extract height specific characteristics from a photo and LiDAR measurements of one or more utility poles. In another example, the processing service 123 can employ a K-means algorithm to perform unsupervised image classifications to determine utility pole characteristics and to identify the particular utility pole (e.g., composite utility poles, steel utility poles, wooden utility poles). In yet another example, the processing service 123 can determine spacing characteristics between electrical components on a particular utility pole based on photos and LiDAR data gathered by the one or more computing devices 103 to identify the necessary adjustments or generating a feasibility score for installing a 5G utility pole module.

The metadata 145 can include any data gathered from the one or more data sources 105. The metadata 145 can include but is not limited to third-party financial data (e.g., distributor pricing, distributor quotes, distributor invoices), contractor data, FCC data, USPS data, accounting data (e.g., internal invoices, purchase orders, purchase order requests), Google maps data, jurisdictional data, environmental systems research institute (ESRI) data, regulatory data, environmental data, and historical data. The metadata 145 can be gathered by the computing environment 101 from the one or more data sources 105. The computing environment 101 can request metadata 145 from the data sources 105 on an automated basis. For example, the computing environment 101 can request metadata 145 from the data sources 105 at 9 AM every Tuesday morning. The computing environment 101 can request metadata 145 in response to performing an analysis on the capture data 141. For example, the computing environment 101 can request federal compliance data from a particular data source 105 when analyzing the size of utility poles to generate a warning when the components of the utility pole are too close to the ground. The computing environment 101 can request metadata 145 from the data sources 105 when generating multi-dimensional models, reports, and/or performing any particular process associated with the utility service construction project.

The process data 147 can include any data generated by the processing service 107. The process data 147 can include but is not limited to multi-dimensional models, accounting reports, orthomosaic models, digital twin models, construction reporting, workflow reports, photo simulations, sheeting/layout automation, stationing automation, PE stamping, underground drawings, utility imports, parcel imports, aerial drawings, pole loading/clearances, drawing revisions, permit application, small cell drawings, site candidate information analyses, environmental reports, 1A surveying (land surveying), pole foundation as-built, underground as-built, construction progress dashboard, project milestone/key performance indicator (KPI) dashboard, customer database sync, and close-out packages. Although discussed as distinct reports and/or multi-dimensional models, the process data 147 generated by the processing service 123 can all be categorized as multi-dimensional models. For example, the orthomosaic model and the sheeting/layout automation can be considered multi-dimensional models. The generation of the process data 147 by the processing service 123 and/or any other service of the computing environment 101 can be discussed in further detail herein.

The project data 149 can include any information associated with the utility service construction project. For example, the project data 149 can include but is not limited to a utility provider name, utility provider addresses, a site location, a site size, a project type, and a project name. The project data 149 can help organize and keep track of active, completed, or abandoned utility service construction projects. The project data 149 can function as a record for the data in the data store 127. For example, on generating a new dataset within the project data 149 for a new utility service construction project, the management service 121 can link the capture data 141, the characteristic data 143, and/or the process data 147 associated with the new utility service construction project to the new dataset.

The routines data 151 stored in the data store 127 can be defined as programs, algorithms, and/or any particular processes used by the processing service 123 to generate the process data 147. The routines data 151 can include but are not limited to statistical analysis routines, image classification algorithms, natural language processing routines, machine learning algorithms, financial analysis routines, image extraction routines, and/or any particular program capable of receiving capture data 141 to generate process data 147. The potential applications and use case scenarios of the routines data 151 are discussed in further detail herein.

The components executed on the computing environment 101, for example, can include list of applications, and other applications, services, processes, systems, engines, or functionalities discussed in detail herein. The computing environment 101 can include a management service 121, a processing service 123, and/or any other services or applications used to maintain the functionality of the construction analysis system 100. Although indicated as separate services, the management service 121 and the processing service 123 can perform similar functionalities. For example, the processing service 123 can perform the same functionalities as the management service 121. By allowing the management service 121 and the processing service 123 to perform similar functionalities, computations and processes can be distributed across the various services.

The management service 121 can facilitate distributing, requesting, and aggregating data across the construction analysis system 100. The management service 121 can include a communication module that interacts with the computing device 103, the data sources 105, and/or any other particular system connected across the network 109. The management service 121 can transmit data processed by the processing service 123 to any particular resource distributed across the network 109. The management service 121 can receive data from the computing devices 103, the data sources 105, and the reporting device 107. For example, the management service 121 can receive data from the computing device 103 for further processing. The management service 121 can include one or more automatic data requests for one or more resources distributed across the network 109. For example, the management service 121 can generate automatic data pulls at 9 A.M. daily from the United States Postal Service (USPS) public server system (where the USPS public server system is an example data source 105) for updates to publically available street and address data. In another example, the management service 121 can generate a data request from the various resources distributed across the network 109 in response to the processing service 123 requesting data for a particular process. The management service 121 can store data in the data store 127. For example, the management service 121 can process data received by the data sources 105. Continuing this example, based on the processes performed by the processing service 123, the management service 121 can determine the type of data gathered from the data sources 105 and store the data in an appropriate location in the data store 127.

The processing service 123 can perform all computational procedures for the computing environment 101 and/or any other resource distributed across the network 109. The processing service 123 can include various statistical, machine learning, natural language processing, and/or application systems to perform operations specific to processes of the construction analysis system 100. For example, the processing service 123 can employ the routines data 151 to analyze the capture data 141. The processing service 123 can generate process data 147 and store the process data 147 in the data store 127. The processing service 123 can perform analyses on the capture data 141 to generate insights associated with the utility service construction project. The potential functionalities and use-case scenarios of the processing service 123 are discussed in further detail herein.

Next, a general description of the operation of the various components of the construction analysis system 100 is provided. To begin, the reporting device 107 can receive a request to log a new utility service construction project. The reporting device 107 can send the request to log the new utility service construction project in the computing environment 101. For example, the management service 121 can generate a new dataset in the project data 149 for the new utility service construction project. The computing environment 101 can render an information request prompt on the display 139. Generating the information request prompt can help facilitate gathering capture data 141 and/or project data 149 from the reporting device 107. For example, the computing environment 101 can generate the information request prompt asking to submit a written description through a text box with the name of the project, the size of the project, known contractors of the project, accounting systems employed, and/or any pertinent information regarding the new utility service construction project. On receiving the responses to the information request prompt, the computing environment can store the data in the capture data 141, the project data 149, and/or any combination thereof.

The processing service 123 can extract features from the capture data 141 and store the identified features in the characteristic data 143 of the data store 127. For example, the processing service 123 can aggregate temperature data associated with the site of the utility service construction project to generate a weather characteristic for the site of the utility service construction project. The processing service 123 can analyze photos, videos, LiDAR data, and/or any pertinent data to extract characteristics associated with fixtures at the site of the utility service construction project. For example, when taking a particular photo of a particular utility pole, the computing device 103 can simultaneously record LiDAR data and location data. The processing service 123 can receive the photo and the associated LiDAR data and location data to extract features associated with the utility pole. For example, the processing service 123 can determine the cardinal direction of the computing device 103 based on the location data. Continuing this example, the processing service 123 can determine the size and dimensionality of the particular utility pole based on the LiDAR data gathered by the computing device 103. The processing service 123 can employ image analysis algorithms to determine the structural integrity of the particular utility pole. For example, the processing service 123 can determine if the particular utility pole is damaged based on cracks identified in the photo gathered by the computing device 103.

The processing service 123 can generate multi-dimensional models for the utility service construction project. Multi-dimensional models can include any model of the site of the utility service construction project. Multi-dimensional models can include but are not limited to three-dimensional models of the site of the utility service construction project, two dimensional models of the site of the utility service construction project, multi-layer models, and/or any other particular model. The processing service 123 can receive a request from the reporting device 107 for generating a particular multi-dimensional model. On receiving the request for generating the particular multi-dimensional model, the processing service 123 can aggregate capture data 141 associated with the particular multi-dimensional model. For example, on receiving a request to generate a two dimensional birds-eye view model of the site of the particular multi-dimensional model, the processing service 123 can aggregate photos recorded by drones and stored in the capture data 141. Continuing this example, the processing service 123 can extract structural features from the photos by using an image feature extraction algorithm from the routines data 151. The image feature extraction algorithm employed by the processing service 123 can identify structures from photos and images to transpose the structures into the two dimensional birds-eye view model. The processing service 123 can us a pixel analysis algorithm from the routines data 151 to determine structures by analyzing shading changes between pixels. The processing service 123 can send the final two-dimensional birds-eye view model to the reporting device 107 for rendering on the display 139.

The processing service 123 can employ the characteristics data to generate the multi-dimensional model. For example, the processing service 123 can receive a request to generate a three-dimensional model for a first fixture and a second fixture within a particular area of interest (e.g., the site of the utility service construction project). The first fixture and the second fixture can include two concurrent utility poles. The processing service 123 can employ videos, photos, LiDAR data, location data, and/or any particular data associated with the first fixture and the second fixture. The processing service 123 can begin generating the three-dimensional model of the first fixture and the second fixture by requesting a map template from the metadata 145. The processing service 123 can use the location data to determine the cardinal orientation and position of the computing device 103 at the moment the computing device 103 aggregated data associated with the first fixture and the second fixture. The processing service 123 can employ the location data and the cardinal orientation of the computing device 103 to determine the location of the first fixture and the second fixture within the map template relative to the computing device 103. The processing service 123 can extract height characteristics associated with the first fixture and the second fixture from the characteristics data 143. The processing service 123 can employ the height characteristics to render the first fixture and the second fixture in the map template with proper proportionalities. The same can be applied to any other object recorded by the computing device 103. The processing service 123 can transpose one or more images recorded by the computing device 103 onto the first fixture and the second fixture rendered in the map template of the three-dimensional model. The processing service 123 can send the three-dimensional model to the reporting device 107 to render the three dimensional device as a computer-aided design (CAD) drawing on the display 139.

The processing service 123 can generate multi-dimensional models with one or more layers defining one or more attributes of the utility service construction project. The one or more layers of the multi-layer model can include but are not limited to an energy layer, a public utility layer, a parcel layer, and a zoning layer. The energy layer can be defined as a layer within the multi-dimensional model that defines the energy infrastructure (e.g., power lines) at the site of the utility service construction project. The public utility layer can be defined as a layer within the multi-dimensional model that defines the public utility infrastructure (e.g., water, gas, sewage) at the site of the utility service construction project. The parcel layer can be defined as a layer within the multi-dimensional model that defines the boundaries of a property or plot of land at the site of the utility service construction project. The zoning layer defines a layer within the multi-dimensional model that defines the known zoning of each parcel at the site of the utility service construction project.

The processing service 123 can generate the one or more layers based on the metadata 145 gathered from the one or more data sources 105. For example, the processing service 123 can generate an energy layer by extracting energy infrastructure maps gathered from the Energy Information Administration (EIA) database. The processing service 123 can generate a public utility layer by extracting public utility data specific to the site of the utility service construction project from the metadata 145, where the computing environment 101 receives public utility data from a federal or local government data sources. The processing service 123 can generate a parcel layer by extracting parcel data from the metadata 145, where the computing environment 101 receives parcel data from the federal or local government data sources. The processing service 123 can generate a zoning layer by extracting zoning data from the metadata 145, where the computing environment 101 receives zoning data from the federal or local government data sources.

The processing service 123 can superimpose each of the one or more layers onto a three-dimensional model. For example, the processing service 123 can generate a three-dimensional model similar to that of the previous disclosed example. The processing service 123 can generate one or more layers to superimpose over the three-dimensional model. For example, the reporting device 107 can generate the three-dimensional model with selectable layers. The reporting device 107 can receive a toggle request to show the energy layer and the parcel layer of the three-dimensional model. The processing service 123 can generate each layer as distinct color transparent features rendered onto the three-dimensional model. For example, the processing service 123 can employ capture data 141 and project data 149 to determine the location of an installed fiber optics internet cable along a road of the utility service construction project. The processing service 123 can illustrate the installed fiber optics internet cable within the three-dimensional model as a semi-transparent blue line along the area it is installed. In another example, the processing service 123 can render the parcel layer by toggling and applying parcel boundaries as yellow lines onto the three-dimensional model.

The processing service 123 can generate the orthomosaic models. The processing service 123 can employ capture data from one or more drones to generate orthomosaic models of the site of the utility service construction model. The drones of the computing devices 103 can take various photos above the site of the utility service construction project. The processing service 123 can extract the photos taken by the drone from the capture data 145 and concatenate each photo to build a full orthomosaic model of the site of the utility service construction project. The processing service 123 can employ various photo correction routines from the routines data 151 to correct distortions generated by the camera of the drone, tilt errors generated by the camera of the drone, perspective view errors, and topographic relief issues.

The processing service 123 can generate one or more digital twin models. The digital twin models can be defined as one or more models that virtual model one or more physical fixtures at the site of the utility service construction project. The processing service 123 can generate digital twins of one or more fixtures. For example, the processing service 123 can receive images and LiDAR data from the data capture device of a utility pole. The images and LiDAR data gathered by the data capture device can include a 360 degree view of the utility pole. The processing service 123 can employ image processing algorithms from the routines to generate, in real-time, a digital twin model of the utility pole. The digital twin model of the utility pole can include proper sizing characteristics in a three-dimensional rendering space. For example, the processing service 123 can render the digital twin model in an adequate CAD file viewer. The digital twin models can be added to the multi-dimensional model and/or the public utility layer as one or more indicators. For example, the reporting device 107 can render the multi-dimensional model with indicators (e.g., a pin on a map at the location of the utility pole) at each of the utility poles. The reporting device 107 can display the CAD file and a preview of the digital twin models on selection of a particular indicator.

The processing service 123 can generate the accounting reports. The processing service 123 can extract accounting data from the metadata 145. The processing service 123 generate accounting reports with total cost of labor, total cost of installation, total cost of materials, estimated budget, current progress relative to the estimated budget, and projected budget. The processing service 123 can employ statistical algorithms from the routines data 151 to generate a budget score rating the likelihood the utility service construction project will be completed within budget. For example, the processing service 123 can extract project data 149 and capture data 141 to determine a completion score of the utility service construction project. Based on the completion score and the known cost of the completed portion of the utility service construction project, the processing service 123 can generate the budget score with a percentage likelihood that the remaining portion of the utility service construction project will be completed on budget. In response to generating a score that indicates the utility service construction project will not be complete on budget, the processing service 123 can employ metadata 145 and historical data stored in the data store 127 of previous utility service construction projects to generate recommendations for saving on labor, materials, and/or any other pertinent components of the utility service construction project to help reduce the total estimated cost. The processing service 123 can render the accounting reports as indicators into the multi-dimensional model. For example, the processing service 123 can generate selectable pins in a three-dimensional map of the utility service construction project. The selectable pins can surface at the location of a particular utility pole, for example, the cost of repair for the particular utility pole.

The processing service 123 can automate sheeting/layout design. The processing service 123 can generate sheeting and layout designs for the utility service construction project in one or more building information modeling (BIM) applications. The processing service 123 can determine from capture data 141 and project data 149 the pertinent layouts associated with the utility service construction project. The processing service 123 can create layouts for one or more layers of the multi-dimensional model. For example, the processing service 123 can generate two-dimensional layouts for a construction layer, the public utility layer, and the energy layer.

The processing service 123 can automate stationing in the multi-dimensional model. The processing service 123 can aggregate capture data 141 to determine stationing within the multi-dimensional model of the utility service construction project. Stationing can refer to the process of defining locations (e.g., stations) separated by a predetermined distance along a path within a construction plan. On generating a multi-dimensional model, the processing service 123 can generate indictors at each generated station.

The processing service 123 can generate professional engineer (PE) stamps. The processing service 123 can generate one or more engineering documents for PE approval and stamping. For example, the processing service 123 can send to the reporting device 107 one or more complete engineering reports and multi-dimensional models for approval and stamping from a professional engineer. The processing service 123 can generate permit applications for submission to local or federal government or approval agencies. The processing service 123 can generate permits according to specific formatting. For example, the reporting device 107 can receive jurisdiction information associated with the utility service construction project and store the jurisdiction information in the project data 149. The processing service 123 can extract the jurisdiction information and render the permit applications according to templates associated with the jurisdiction information.

The processing service 123 can generate underground drawings. Underground drawings can be defined as illustrations of various underground components of a particular construction. The underground drawings can be associated with the multi-dimensional models. For example, the underground drawings can be considered as a layer of the multi-layered model. The processing service 123 can generate underground drawings for the utility service construction project. For example, the processing service 123 can receive location data from one or more computing devices 103 pertaining to a path for installing a sewage pipeline in a neighborhood under development. The processing service 123 can render the location data as a path on a map of the site of the utility service construction project. The processing service 123 can generate an indicator pointing to the path and when selected surfaces specific attributes associated with the sewage pipeline (e.g., depth in the ground, width, coordinate locations).

The processing service 123 can generate drawing revisions. The processing service 123 can receive drawings associated with the utility service construction project. The processing service can employ an analysis routine from the routines data 151 to determine errors in the drawings received from the reporting device 107. For example, the processing service 123 can receive an electrical drawing for powering small cell systems in a neighborhood. The processing service 123 can employ the analysis routine to identify inefficiencies in the drawing, incorrect symbols in the drawing, incorrect dimensions, incorrect orientation, incorrect sizing, and/or any other error present in the drawing. The processing service 123 can render indicators on a digital copy of the drawing pointing to the identified errors from the analysis routine. The processing service 123 can generate a correctness score by averaging the number of errors and comparing the average number of errors to historical averages for similar utility service construction projects. The processing service 123 can generate recommendations for fixing identified errors. For example, the processing service 123 can calculate the correct distance between two nodes of a small sell system in response to the processing service 123 identifying an incorrect distance.

The processing service 123 can perform site candidate information analyses. After gathering data from one or more computing devices 103 at one or more sites for the utility service construction project, the processing service 123 can generate site ratings for the one or more sites. For example, based on the project data 149 and the capture data 141, the processing service 123 can score the one or more sites of the utility service construction project. The processing service 123 can extract a project type from the project data 149. The processing service 123 can extract project specific metadata from the metadata 145 associated with the project type of the utility service construction project. The project specific metadata can define scoring parameters that when met or surpassed categorize the site of the utility service construction project as an adequate site. The processing service 123 can extract characteristic data 143 associated with the site of the utility service construction project. The processing service 123 can generate one or more site scores for the specific site. For example, the processing service can perform a site analysis routine from the routines data 151 on the characteristic data 143 to generate the site scores. The processing service 123 can compare the site scores to the scoring parameters and generate a site viability recommendation regarding the one or more sites of the utility service construction project.

The processing service 123 can generate the construction progress dashboard. The processing service 123 can analyze project data 149 characteristic data 143, and metadata 145 to determine in real-time the status of the utility service construction project. The processing service 123 can render the construction progress dashboard through the display 139. The construction progress dashboard can include but is not limited to project milestones, key performance indicators (KPI), workflow reports, construction reports, budgeting reports, and/or any other metric used to quantify the progress of the utility service construction project. The processing service 123 can generate invoices and accruals associated with the utility service construction project. The construction progress dashboard can render the invoices and accruals and can include a payment dashboard for receiving payment information associated with the invoices and accruals.

The processing service 123 can generate a closeout package. The closeout package can be defined as a summary report that illustrates a successful completion of the utility service construction project. The processing service 123 can receive formatting and content parameters from the reporting device 107. The processing service 123 can employ the formatting and content parameters to generate the closeout package specifically tailored to the particular utility service construction project. The processing service 123 can automatically generate the closeout package based on the expected completion data extracted from the project data 149. The processing service 123 can send the closeout package to the reporting device 107.

The reporting device 107 and/or computing device 103 can generate an augmented reality on the display 139. On receiving a multi-dimensional model, a digital twin, and/or any particular three-dimensional rendering from the processing service 123, the reporting device 107 and/or computing device 103 can facilitate an augmented reality view at the site of the utility service construction project. For example, the reporting device 107 and/or computing device 103 can receive a three-dimensional model of a new utility pole. The three-dimensional model can include associated location data that indicates the installation location of the utility pole. The reporting device 107 and/or computing device 103 can employ cameras to receive a live feed of the site of the utility service construction project. On recognizing that the location of the reporting device 107 matches the location data associated with the three-dimensional model and the reporting device 107 is pointed in the correct direction, the reporting device 107 can superimpose a virtual rendering of the new utility pole onto the live feed received from the camera. The display 139 can render the live feed and the superimposed virtual rendering of the new utility pole. The reporting device 107 and/or the computing device 103 can employ LiDAR sensors to properly orient, size, and position the virtual rendering of the new utility pole relative to the live feed.

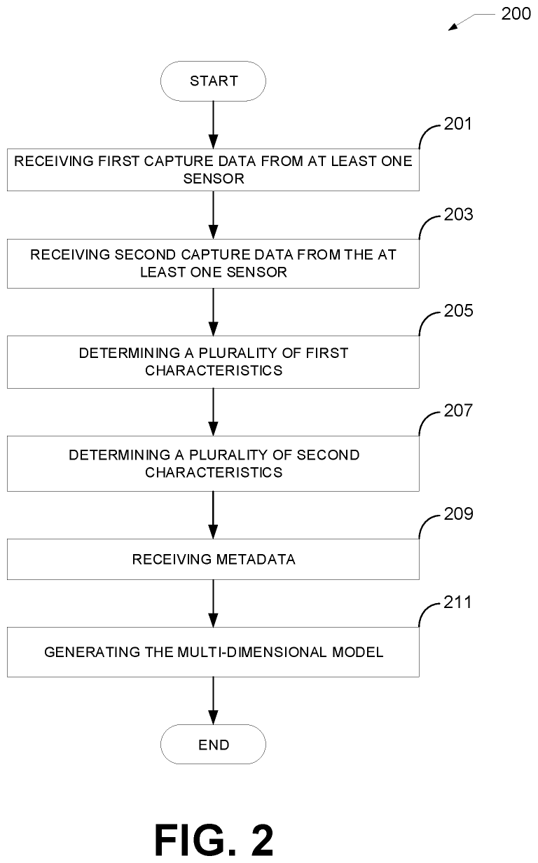

Referring now to FIG. 2, illustrated is a flowchart of a process 200, according to one embodiment of the present disclosure. The process 200 can represent an example technique for generating the multi-dimensional models through the construction analysis system 100. For the flowcharts discussed in FIGS. 2-5, it may be understood that the order of any particular box can be executed at any particular step in the associated process unless otherwise indicated differently in the written description.

At box 201, the process 200 can include receiving a first capture data from the at least one sensor 129. The computing environment 101 can receive the first capture data recorded by one or more sensors 129 of a first data source (e.g., the data capture device of the computing devices 103). The first capture data can relate to a first fixture within a particular area of interest. For example, the first capture data can include one or more images, LiDAR data, and location data associated with a first utility pole within the particular area of interest at the site of the utility service construction project. The computing device 103 deployed at the site of the utility service construction project to record the first capture data. The management service 121 can store the first capture data in the capture data 141 of the data store 127.

At box 203, the process 200 can include receiving a second capture data from the at least one sensor 129. The computing environment 101 can receive the second capture data recorded by one or more sensors 129 of the first data source. The second capture data can relate to a second fixture within the particular area of interest. For example, the second capture data can include a second set of images, LiDAR data, and location data of a second utility pole. The data capture device of the computing devices 103 can capture the second capture data. The data capture device can record the second capture data of the second utility pole within the particular area of interest at the site of the utility service construction project. For example, the first utility pole and the second utility pole can be two adjacent utility poles within the particular area of interest. The computing devices 103 can continue to record data for two or more fixtures in the particular area of interest.

At box 205, the process 200 can include determining one or more first characteristics. The processing service 123 can determine the first characteristics for the first fixture based on the first capture data. For example, first characteristics can include but are not limited to a utility pole type, a number of attached cables, types of cables, a utility pole height, a utility pole diameter, jurisdiction and laws associate with the location of the first utility pole, and construction type. The processing service 123 can employ one or more routines from the routines data 151 to extract features and characteristics from the capture data 141. For example, the processing service 123 can employ a convolution neural network to identify the type of utility pole for the first utility fixture, such as, for example a utility pole. In another example, the processing service 123 can employ statistical averaging to determine the height of the first utility pole based on the LiDAR data.

At box 207, the process 200 can include determining one or more second characteristics. The processing service 123 can determine the second characteristics for the second fixture based on the second capture data. The second characteristics can be substantially similar to the first characteristics. The processing service 123 can perform similar routines on the second capture data as the first capture data to extract the second characteristics.

At box 209, the process 200 can include receiving metadata 145. The computing environment 101 can receive metadata 145 associated with a subset of the particular area of interest from a second data source (e.g., one or more of the data sources 105). In some embodiments, the computing environment 101 can receive metadata 145 associated with an area partially including the subset of the particular area of interest. In one embodiment, the computing environment 101 can modify the metadata 145 to remove data associated with areas outside the particular area of interest. The management service 121 can request data from the second data source based on the location of the subset of the particular area of interest. For example, on receiving project data 149 and/or location data from one or more capture devices 103 defining the location of the particular area of interest, the management service 121 can perform a data scraping technique from publicly and privately available data sources 105 for federal mandated codes and standards associated with the particular area of interest. In another example, the management service 121 can request metadata 145 at specific times for an area larger than the particular area of interest. The processing service 123 can analyze the characteristic data 143 and the capture data 141 to request metadata 145 specific to the characteristic data 143 and the capture data 141. For example, on identifying one or more high voltage cables extending from the first utility pole to the second utility pole, the processing service 123 can request metadata specific to publicly available utility maps for high voltage cables within the area of interest.

At box 211, the process 200 can include generating the multi-dimensional model. The processing service 123 can generate the multi-dimensional model of the particular area of interest including the first fixture based on the plurality of first characteristics, the second fixture based on the plurality of second characteristics, and at least one indicator based on the metadata. The processing service 123 can generate the multi-dimensional model as a two-dimensional map, a three-dimensional map, and/or a CAD drawing of the particular area of interest. The processing service 123 can employ the first characteristics of the first utility pole to match the location of the first utility pole from the capture data 141 with a coordinate system of the multi-dimensional model. The processing service 123 can employ the LiDAR characteristics of the first utility pole to determine the sizing of the first utility pole within the multi-dimensional model. The processing service 123 can employ images taken of the first utility pole to overlay onto the multi-dimensional model. For example, on rendering an object representing the first utility pole in a virtual three-dimensional space, the processing service 123 can overlay the images of the first utility pole onto the object representing the utility pole. The processing service 123 can repeat rendering one or more fixtures in the multi-dimensional model. For example, the processing service 123 can add the second utility pole, a building, vegetation, sidewalks, and/or any particular object or fixture present in the capture data 141 and characteristic data 143. The processing service 123 can generate one or more indicators in the multi-dimensional model according to the metadata. For example, the processing service 123 can render a pin on a three-dimensional map that gives details on the first utility pole and second utility pole (e.g., owners, types of cables used, types of data and/or energy transmission, cost, cost of repair). The processing service 123 can send the multi-dimensional model to the reporting device 107 for rendering on the display 139. The reporting device 107 can surface one or more fields, such as a text box, on the display 139 describing the content of the indicator on receiving a request to open the indicator.

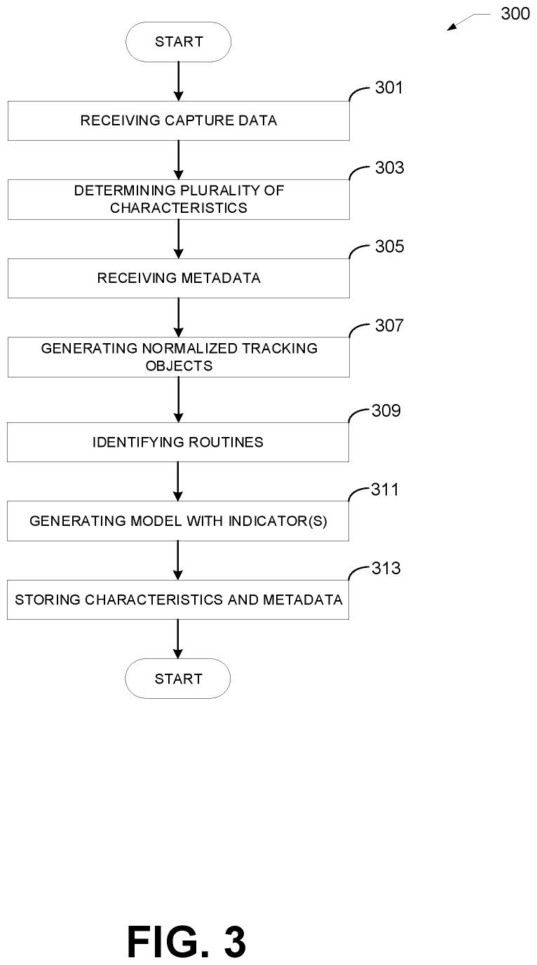

Referring now to FIG. 3, illustrated is a process 300, according to one embodiment of the present disclosure. The process 300 can represent a technique for generating the multi-dimensional model using normalized tracking objects through the construction analysis system.

At box 301, the process 300 can include receiving capture data 141 from one or more computing devices 103. The computing environment 101 can receive capture data 141 from the computing devices 103 deployed at the site of the utility service construction project. The capture data 141 can include data associated with one or more fixtures at the site of the utility service construction project.

At box 303, the process 300 can include determining one or more characteristics data 143 from the capture data 141. The processing service 123 can extract characteristics data 143 from the capture data 141. The characteristics data 143 can include features associated with the capture data 141. The processing service 123 can extract characteristic data 143 from the capture data 141 substantially similarly to extracting the plurality of first characteristic data 143 from the first capture data of process 200.

At box 305, the process 300 can include receiving metadata 145 from the one or more data sources 105. The processing service 123 and/or the management service 121 can receive metadata 145 from the data sources 105. Receiving and/or requesting the metadata 145 from the one or more data sources 105 can be substantially similar to the process of extracting metadata 145 from the second data source of process 200.

At box 307, the process 300 can include generating normalized tracking objects. The processing service 123 can generate normalized tracking objects for use in the multi-dimensional model and/or the augmented reality rendering of the one or more fixtures. Normalized tracking objects can be defined as a virtually rendered multi-dimensional object created by the processing service 123 for insertion into a photo, video, and/or multi-dimensional model. The processing service 123 can generate normalized tracking objects by employing a photogrammetry system. The processing service 123 can apply the photogrammetry system to capture data 141 and characteristics data 143 associated with the normalized tracking object. For example, the processing service 123 can use LiDAR data and images from the capture device 103 to gather characteristics of the fixture (e.g., utility pole) and employ the photogrammetry system to generate a three-dimensional model of the fixture. On generating the three-dimensional model, the processing service 123 can store the three-dimensional model as a particular normalized tracking object in the process data 147.

At box 309, the process 300 can include identifying routines. The processing service 123 can identify routines from the routines data 151. The processing service 123 can identify routines to apply to the normalized tracking object, the characteristic data 143, the metadata 145, and/or the multi-dimensional model and reports. The routines (also referred to as processes) can be defined as one or more algorithms, programs, and/or analyses performed by the processing service 123 to analyze capture data 141, characteristics data 143, metadata 145, process data 147, and/or project data 149 to generate a particular output. For example, the routines data 151 can include a process for performing a statistical analysis on various lengths of fiber-optic internet cables installed at 100 utility service construction projects to generate a report on regional differences in fiber-optic internet cable lengths. The processing service 123 can receive a request from the reporting device 107 to employ a particular routine from the routine data 151 to perform a particular analysis on the data in the data store 127. For example, the processing service 123 can receive a request to generate an orthomosaic image of the subset of the particular area of interest. The processing service 123 can employ an orthomosaic design system from the routines data 151 to concatenate images of the subset of the particular area to form one continuous orthomosaic image, correct the orthomosaic image for errors, and generate indicators associated with geographical information system (GIS) databases. For example, the indicators can include transportation information, building data, vegetation data, boundary data (parcel data), and/or elevation data.

At box 311, the process 300 can include generating a model with indicators. The processing service 123 can generate one or more multi-dimensional models with one or more indicators. The processing service 123 can generate a three-dimensional model of the particular area of the utility service construction project. For example, the processing service 123 can render the one or more normalized tracking objects in a location that corresponds with the same non-virtual location. The processing service 123 can generate indicators, such as pins, at various locations throughout the three-dimensional model. For example, the processing service can generate project management indicators generated from the project management data stored in the metadata 145 and extracted from the data source 105. The project management indicators can include, for example, development statuses for each location marked with the project management indicators. The development statuses can include the current progress, expected time of completion, current cost of construction, total budget, and/or any particular status associated with the development of the utility service construction project.

At box 313, the process 300 can include storing extracted characteristics and the metadata in the data store 127. The processing service 123 can store the extracted characteristics from the capture data 141 and the metadata from the data sources 105 in the characteristics data 143 and the metadata 145, respectively. The management service 121 can link the extracted characteristics, the capture data 141, and the metadata 145 to an associated utility service project stored in the project data 149.

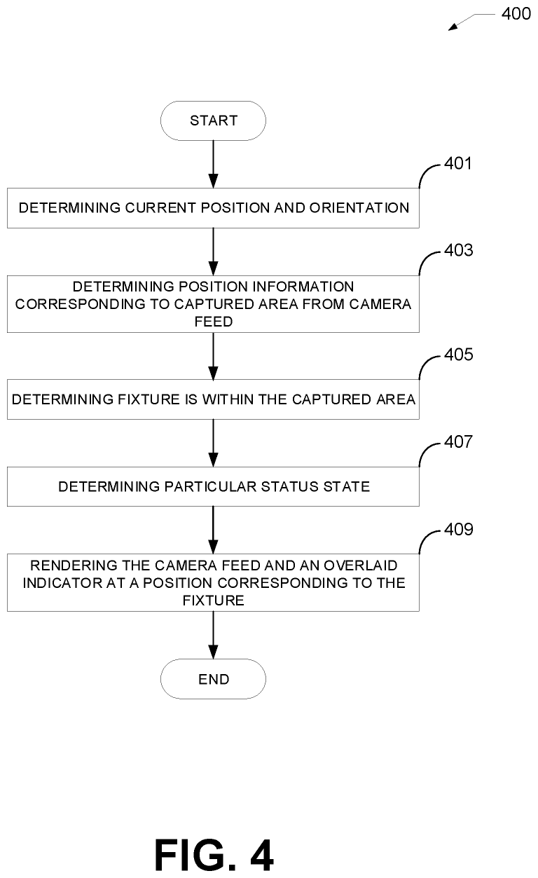

Referring now to FIG. 4, illustrated is a flowchart of a process 400, according to one embodiment of the present disclosure. The process 400 can include a technique for generating a real-time indicator on a display 139 of a reporting device 107 at the particular area interest of the utility service construction project. The techniques performed by the processor 131 can equally be performed by the computing environment 101. Although discussed in the context of the data capture device, the techniques of the process 400 can be applied to any particular computing device 103 and/or reporting device 107.

At box 401, the process 400 can include determining current position and orientation. The processor 131 of the data capture device can determine the current position and orientation of the particular capture device 103. The processor 131 can receive location data from the sensors 129 (e.g., GPS sensor, gyroscope, accelerometer) to determine the current location of the data capture device. For example, the processor 131 can receive GPS data describing the current longitude and latitude of the particular data capture device. The processor 131 can employ the gyroscopic data to determine the orientation of the data capture device relative to the ground. The processor 131 can use the GPS sensor to determine the cardinal direction the data capture device.

At box 403, the process 400 can include determining position information corresponding to a captured area from a camera feed. The processor 131 can determine the position information of images or videos input by the camera of the sensors 129 in real-time. The processor 131 can employ the cardinal orientation of the data capture device relative to the longitude and latitude recordings to orient the capture area from the camera feed. For example, the processor 131 can receive the camera feed with corresponding GPS data and orientation data. The processor 131 can employ the corresponding GPS data and orientation data to determine the direction of the data capture device while generating the camera feed. The processor 131 can continually label the orientation of the camera feed using the GPS data and the orientation data.

At box 405, the process 400 can include determining that a fixture is within the captured area based on the positional information and the multi-dimensional model. The processor 131 can determine that the fixture is within the captured area based on the positional information and the multi-dimensional model. The processor 131 can reference the location of the data capture device relative to the multi-dimensional model. The processor 131 can determine a correct location of the fixture by identifying a virtual fixture in the three dimensional model in the orientation and direction of the data capture device. For example, when the data capture device points in the direction of a fixture (or a fixture yet to be installed) the processor 131 can reference the multi-dimensional model to confirm the presence of the fixture. The processor 131 can employ image processing systems from the routine data 151 to determine the presence of the fixture.

At box 407, the process 400 can include determining status states. The processor 131 can determine a particular state of a plurality of status states based on a current status of a project associated with the fixture. The processor 131 can determine the state of the project associated with the fixture. The state can defined the current progress of the fixture in the utility service construction project. The status states can correspond to one or more indicators. For example, the multi-dimensional model can include indicators associated with the fixture in the direction of the data capture device. Continuing this example, the processor 131 can extract from the indicators within the multi-dimensional model the status information and/or particular state (e.g., a percentage completion) associated with the fixture in the direction of the data capture device of the computing device 103.

At box 409, the process 400 can include rendering the camera feed and an overlaid indicator at a position corresponding to the fixture. The processor 131 can render the camera feed and the overlaid indicator at the position corresponding to the fixture. The processor 131 can superimpose a surfaced text box at the location of the fixture within the camera feed detailing the particular status associated with the fixture. The processor 131 can render the camera feed with the surfaced text box of the indicator on a display of the computing device 103. The processor can render the indicator in the camera feed based on the location and orientation of the data capture device relative to the multi-dimensional model and/or a real-time location of the data capture device. The indicator rendered in the camera feed of the data capture device can include any particular indicator. For example, the indicator can include a permit status extracted from permit data illustrating the status of the permit associated with the fixture and/or the utility service construction project.

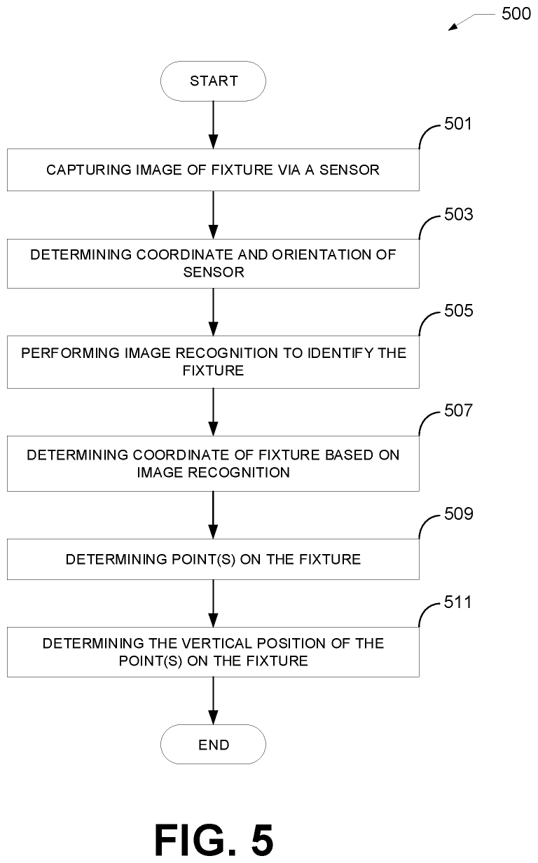

Referring now to FIG. 5, illustrated is a flowchart of the process 500, according to one embodiment of the present disclosure. The process 500 can include a technique for determining the dimensionality of the fixture recorded by the computing device 103.

At box 501, the process 500 can include capturing an image of the fixture through a sensor 129 of the computing device 103. The sensors 129 can capture the image of the fixture. For example, the data capture device can include a camera for capturing images at the particular area of interest of the utility service construction project.

At box 503, the process 500 can include determining the coordinates and orientation of the sensor 129. The processor 131 can determine the coordinates and the orientation of the sensor 129 at the moment of capturing the image of the fixture. The processor 131 can employ onboard GPS sensors and gyroscopes to determine the orientation of the data capture device when taking the photo of the fixture. For example, the processor 131 can request GPS data, gyroscopic data, and LiDAR data each time the data capture device captures an image. The processor 131 can determine the cardinal orientation of the sensor by analyzing the GPS data and the gyroscopic data. The processor 131 can store a first coordinate for the location of the sensor and/or the data capture device in the data store 127.

At box 505, the process 500 can include performing image recognition to identify the fixture. The processor 131 can perform image recognition techniques on the image of the data capture device to identify the fixture. For example, the processor 131 can employ a K-nearest neighbor algorithm to determine the presence of the fixture. The processor 131 can employ any particular image recognition technique from the routines data 151 to identify the presence of the fixture.

At box 507, the process can include determining a second coordinate associated with the fixture based on the image recognition of the fixture, the first coordinate of the data capture device, and the orientation of the first data capture device. The processor 131 can determine the second coordinate associated with the fixture based on the image recognition of the fixture, the first coordinate of the data capture device, and the orientation of the data capture device. The processor 131 can employ the LiDAR data to determine the distance between the fixture and the data capture device. For example, the LiDAR data can represent a distance vector between the fixture and the data capture device. The processor 131 can sum the distance vector with the first coordinate of the data capture device to generate the second coordinate. The second coordinate can illustrate the location of the fixture analyzed by the data capture device.

At box 509, the process 500 can include determining one or more points on the fixture. The processor 131 can determine one or more points on the fixture. The processor 131 can select a point on the fixture based on the second coordinate, the LiDAR data, the image recognition of the fixture, and/or the first coordinate of the data capture device. The point can represent any location different to the second coordinate on the fixture. For example, the second coordinate can define a location of the base of the fixture (e.g., utility pole) and a first point can define a location of a top of the fixture.

At box 511, the process 500 can include determining at least on vertical position of the points on the fixture. The processor 131 can determine the at least one vertical position of the at least one point on the first fixture. The vertical position can represent a vertical distance defining the size of the fixture. For example, the processor can calculate a vertical position by defining a distance vector between the second coordinate and the one or more points on the fixture.

The embodiments were chosen and described to explain the principles of the innovations and their practical application to enable others skilled in the art to utilize the innovations and various embodiments and with various modifications as are suited to the particular use contemplated. Alternative embodiments will become apparent to those skilled in the art to which the present innovations pertain without departing from their spirit and scope. Accordingly, the scope of the present innovations is defined by the appended claims rather than the foregoing description and the exemplary embodiments described therein.

From the foregoing, it will be understood that various aspects of the processes described herein are software processes that execute on computer systems that form parts of the system. Accordingly, it will be understood that various embodiments of the system described herein are generally implemented as specially configured computers including various computer hardware components and, in many cases, significant additional features as compared to conventional or known computers, processes, or the like, as discussed in greater detail herein. Embodiments within the scope of the present disclosure also include computer-readable media for carrying or having computer-executable instructions or data structures stored thereon. Such computer-readable media can be any available media that can be accessed by a computer, or downloadable through communication networks. By way of example, and not limitation, such computer-readable media can comprise various forms of data storage devices or media such as RAM, ROM, flash memory, EEPROM, CD-ROM, DVD, or other optical disk storage, magnetic disk storage, solid state drives (SSDs) or other data storage devices, any type of removable non-volatile memories such as secure digital (SD), flash memory, memory stick, etc., or any other medium which can be used to carry or store computer program code in the form of computer-executable instructions or data structures and which can be accessed by a computer.

When information is transferred or provided over a network or another communications connection (either hardwired, wireless, or a combination of hardwired or wireless) to a computer, the computer properly views the connection as a computer-readable medium. Thus, any such a connection is properly termed and considered a computer-readable medium. Combinations of the above should also be included within the scope of computer-readable media. Computer-executable instructions comprise, for example, instructions and data, which cause a computer to perform one specific function or a group of functions.

Those skilled in the art will understand the features and aspects of a suitable computing environment in which aspects of the disclosure may be implemented. Although not required, some of the embodiments of the claimed innovations may be described in the context of computer-executable instructions, such as program modules or engines, as described earlier, being executed by computers in networked environments. Such program modules are often reflected and illustrated by flow charts, sequence diagrams, exemplary screen displays, and other techniques used by those skilled in the art to communicate how to make and use such computer program modules. Generally, program modules include routines, programs, functions, objects, components, data structures, application programming interface (API) calls to other computers whether local or remote, etc. that perform particular tasks or implement particular defined data types, within the computer. Computer-executable instructions, associated data structures and/or schemas, and program modules represent examples of the program code for executing steps of the methods disclosed herein. The particular sequence of such executable instructions or associated data structures represent examples of corresponding acts for implementing the functions described in such steps.

Those skilled in the art will also appreciate that the claimed and/or described systems and methods may be practiced in network computing environments with many types of computer system configurations, including personal computers, smartphones, tablets, hand-held devices, multi-processor systems, microprocessor-based or programmable consumer electronics, networked PCs, minicomputers, mainframe computers, and the like. Embodiments of the claimed innovation are practiced in distributed computing environments where tasks are performed by local and remote processing devices that are linked (either by hardwired links, wireless links, or by a combination of hardwired or wireless links) through a communications network. In a distributed computing environment, program modules may be located in both local and remote memory storage devices.

An exemplary system for implementing various aspects of the described operations, which is not illustrated, can include a computing device including a processing unit, a system memory, and a system bus that couples various system components including the system memory to the processing unit. The computer will typically include one or more data storage devices for reading data from and writing data to. The data storage devices provide nonvolatile storage of computer-executable instructions, data structures, program modules, and other data for the computer.

Computer program code that implements the functionality described herein typically comprises one or more program modules that may be stored on a data storage device. This program code, as is known to those skilled in the art, usually can include an operating system, one or more application programs, other program modules, and program data. A user may enter commands and information into the computer through keyboard, touch screen, pointing device, a script containing computer program code written in a scripting language or other input devices (not shown), such as a microphone, etc. These and other input devices are often connected to the processing unit through known electrical, optical, or wireless connections.

The computer that effects many aspects of the described processes will typically operate in a networked environment using logical connections to one or more remote computers or data sources, which are described further below. Remote computers may be another personal computer, a server, a router, a network PC, a peer device or other common network node, and typically include many or all of the elements described above relative to the main computer system in which the innovations are embodied. The logical connections between computers include a local area network (LAN), a wide area network (WAN), virtual networks (WAN or LAN), and wireless LANs (WLAN) that are presented here by way of example and not limitation. Such networking environments are commonplace in office-wide or enterprise-wide computer networks, intranets, and the Internet.

When used in a LAN or WLAN networking environment, a computer system implementing aspects of the innovation is connected to the local network through a network interface or adapter. When used in a WAN or WLAN networking environment, the computer may include a modem, a wireless link, or other mechanisms for establishing communications over the wide area network, such as the Internet. In a networked environment, program modules depicted relative to the computer, or portions thereof, may be stored in a remote data storage device. It will be appreciated that the network connections described or shown are exemplary and other mechanisms of establishing communications over wide area networks or the Internet may be used.

Clause 1. A system comprising: a data store; and at least one computing device in communication with the data store, wherein the at least one computing device is configured to: receive first capture data from at least one sensor associated with a first data source, the first captured data relating to a first fixture within a particular area of interest; receive second capture data from the at least one sensor associated with the first data source, the second captured data relating to a second fixture within the particular area of interest; determine a plurality of first characteristics for the first fixture based on the first capture data; determine a plurality of second characteristics for the second fixture based on the second capture data; receive metadata associated with a subset of the particular area of interest from a second data source; and generate a multi-dimensional model of the particular area of interest comprising the first fixture based on the plurality of first characteristics, the second fixture based on the plurality of second characteristics, and at least one indicator based on the metadata.

Clause 2. The system of clause 1 or any other clause herein, wherein the data store comprises a plurality of routines and the at least one computing device is further configured to: identify a particular routine of the plurality of routines; and perform the particular routine to generate the multi-dimensional model of the particular area of interest.

Clause 3. The system of clause 1 or any other clause herein, wherein the at least one computing device is further configured to store the plurality of first characteristics, the plurality of second characteristics, and the metadata in the data store.

Clause 4. The system of clause 1 or any other clause herein, wherein the multi-dimensional model comprises a three-dimensional model.

Clause 5. The system of clause 1 or any other clause herein, wherein the at least one computing device is further configured to generate the multi-dimensional model by generating a computer-aided design file corresponding to the particular area of interest comprising the first fixture, the second fixture, and the at least one indicator.

Clause 6. The system of clause 1 or any other clause herein, wherein the at least one sensor comprises a distance sensor and a camera.

Clause 7. A non-transitory computer-readable medium embodying a program that, when executed by at least one computing device, causes the at least one computing device to: receive first capture data from at least one sensor associated with a first data source, the first captured data relating to a first fixture within a particular area of interest; receive second capture data from the at least one sensor associated with the first data source, the second captured data relating to a second fixture within the particular area of interest; determine a plurality of first characteristics for the first fixture based on the first capture data; determine a plurality of second characteristics for the second fixture based on the second capture data; receive metadata associated with a subset of the particular area of interest from a second data source; and generate a multi-dimensional model of the particular area of interest comprising the first fixture based on the plurality of first characteristics, the second fixture based on the plurality of second characteristics, and at least one indicator based on the metadata.

Clause 8. The non-transitory computer-readable medium of clause 7 or any other clause herein, wherein the multi-dimensional model comprises at least one layer comprising at least one of: an energy layer, a public utility layer, a parcel layer, and a zoning layer, wherein the at least one layer is generated based on the metadata.

Clause 9. The non-transitory computer-readable medium of clause 7 or any other clause herein, wherein the program further causes the at least one computing device to: receive a plurality of images corresponding to the particular area of interest; generate an orthomosaic image corresponding to another subset of the particular area of interest based on the plurality of images; and generate the multi-dimensional model based on the orthomosaic image.

Clause 10. The non-transitory computer-readable medium of clause 7 or any other clause herein, wherein the second data source comprises a geographical information system (GIS) database and the at least one indicator corresponds to an indication of at least one of: transportation information, building data, vegetation data, boundary data, or elevation data.

Clause 11. The non-transitory computer-readable medium of clause 7 or any other clause herein, wherein the second data source comprises project management data and the at least one indicator comprises a plurality of indicators individually corresponding to a development status for a respective one of a plurality of project components.

Clause 12. A method, comprising: receiving, via at least one computing device, first capture data from at least one sensor associated with a first data source, the first captured data relating to a first fixture within a particular area of interest; receiving, via the at least one computing device, second capture data from the at least one sensor associated with the first data source, the second captured data relating to a second fixture within the particular area of interest; determining, via the at least one computing device, a plurality of first characteristics for the first fixture based on the first capture data; determining, via the at least one computing device, a plurality of second characteristics for the second fixture based on the second capture data; receiving, via the at least one computing device, metadata associated with a subset of the particular area of interest from a second data source; and generating, via the at least one computing device, a multi-dimensional model of the particular area of interest comprising the first fixture based on the plurality of first characteristics, the second fixture based on the plurality of second characteristics, and at least one indicator based on the metadata.

Clause 13. The method of clause 12 or any other clause herein, further comprising: generating, via the at least one computing device, a plurality of normalized tracking objects based on the plurality of first characteristics, the plurality of second characteristics, and the metadata; and storing, via the at least one computing device, the plurality of normalized tracking objects in a data store.

Clause 14. The method of clause 12 or any other clause herein, further comprising: determining, via a mobile computing device, a current position and orientation of the mobile computing device; determining, via the mobile computing device, positional information corresponding to a captured area from a camera feed of the mobile computing device; determining that the first fixture is within the captured area based on the positional information and the multi-dimensional model; and rendering, on a display of the mobile computing device, the camera feed and an overlaid indicator at a position within the captured area corresponding to the first fixture.

Clause 15. The method of clause 14 or any other clause herein, further comprising determining a particular state of a plurality of status states based on a current status of a project associated with the first fixture, wherein the plurality of status states individually correspond to a respective one of a plurality of indicator graphics and the overlaid indicator comprises the respective one of the plurality of indicator graphics that corresponds to the particular state.

Clause 16. The method of clause 12 or any other clause herein, wherein determining the plurality of first characteristics for the first fixture comprises: capturing, via the at least one computing device, an image of the first fixture via the at least one sensor; determining, via the at least one computing device, a first coordinate and an orientation of the at least one sensor when the image is captured; performing, via the at least one computing device, an image recognition on the image to identify the first fixture in the image; and determining, via the at least one computing device, a second coordinate of the first fixture based on the image recognition, the first coordinate of the at least one sensor, and the orientation of the at least one sensor, wherein the plurality of first characteristics comprises the first coordinate of the first fixture.

Clause 17. The method of clause 16 or any other clause herein, wherein determining the plurality of first characteristics for the first fixture comprises: determining, via the at least one computing device, at least one point on the first fixture; and determining, via the at least one computing device, at least one vertical position of the at least one point on the first fixture, wherein the plurality of first characteristics comprises the at least one vertical position.

Clause 18. The method of clause 12 or any other clause herein, wherein the second data source comprises permit data and the at least one indicator comprises a plurality of indicators individually corresponding to a permit status for a respective one of a plurality of project components.

Clause 19. The method of clause 12 or any other clause herein, further comprising: generating, via the at least one computing device, an invoice for at least one of the plurality of project components, wherein the second data source is accounting data; and transmitting, via the at least one computing device, the invoice for the at least one of the plurality of project components to a user account associated with the at least one of the plurality of project components.

Clause 20. The method of clause 12 or any other clause herein, further comprising: receiving, via the at least one computing device, a request for a report corresponding to the particular area of interest; generating, via the at least one computing device, the report based on the multi-dimensional model; and transmitting, via the at least one computing device, the report based on the request.

While various aspects have been described in the context of a preferred embodiment, additional aspects, features, and methodologies of the claimed innovations will be readily discernible from the description herein, by those of ordinary skill in the art. Many embodiments and adaptations of the disclosure and claimed innovations other than those herein described, as well as many variations, modifications, and equivalent arrangements and methodologies, will be apparent from or reasonably suggested by the disclosure and the foregoing description thereof, without departing from the substance or scope of the claims. Furthermore, any sequence(s) and/or temporal order of steps of various processes described and claimed herein are those considered to be the best mode contemplated for carrying out the claimed innovations. It should also be understood that, although steps of various processes may be shown and described as being in a preferred sequence or temporal order, the steps of any such processes are not limited to being carried out in any particular sequence or order, absent a specific indication of such to achieve a particular intended result. In most cases, the steps of such processes may be carried out in a variety of different sequences and orders, while still falling within the scope of the claimed innovations. In addition, some steps may be carried out simultaneously, contemporaneously, or in synchronization with other steps.

The embodiments were chosen and described to explain the principles of the claimed innovations and their practical application so as to enable others skilled in the art to utilize the innovations and various embodiments and with various modifications as are suited to the particular use contemplated. Alternative embodiments will become apparent to those skilled in the art to which the claimed innovations pertain without departing from their spirit and scope. Accordingly, the scope of the claimed innovations is defined by the appended claims rather than the foregoing description and the exemplary embodiments described therein.

1. A system comprising:
one or more processors; and
memory coupled with the one or more processors, the memory storing executable instructions that when executed by the one or more processors cause the one or more processors to effectuate operations comprising:
receiving, from at least one sensor associated with a first data source, first capture data associated with a first fixture, wherein the first fixture is associated with a construction project within an area of interest;
receiving, from the at least one sensor, second capture data to associated with a second fixture, wherein the second fixture is associated with the construction project within the area of interest;
determining, based on the first capture data, a plurality of first characteristics associated with the first fixture;
determining, based on the second capture data, a plurality of second characteristics associated with the second fixture;
receiving, from a second data source, metadata associated with a subset of the area of interest;
generating, based on the plurality of first characteristics and the plurality of second characteristics, a multi-dimensional model associated with the particular area of interest;
determining, based on the metadata, at least one development status associated with the construction project; and
transmitting, based on the development status, a closeout package associated with the construction project.

2. (canceled)

3. The system of claim 1, wherein the operations further comprise storing, in a data store, the plurality of first characteristics, the plurality of second characteristics, and the metadata.

4. The system of claim 1, wherein the multi-dimensional model comprises a three-dimensional model.

5. The system of claim 1, wherein the operations further comprise generating a computer-aided design file corresponding to the area of interest, the computer aided design file is associated with the first fixture and the second fixture, and the multi-dimensional model comprises the computer-aided design file.

6. The system of claim 1, wherein the at least one sensor comprises a distance sensor and a camera.

7. A non-transitory computer-readable medium storing instructions that, when executed, cause:
receiving, from at least one sensor associated with a first data source, first capture data associated with a first fixture, wherein the first fixture is associated with a construction project within an area of interest;
receiving, from the at least one sensor, second capture data associated with a second fixture, wherein the second fixture is associated with the construction project within the area of interest;
determining, based on the first capture data, a plurality of first characteristics associated with the first fixture;
determining, based on the second capture data, a plurality of second characteristics associated with the second fixture;
receiving, from a second data source, metadata associated with a subset of the area of interest;
generating, based on the plurality of first characteristics and the plurality of second characteristics, a multi-dimensional model associated with the area of interest;
determining, based on the metadata, at least one development status associated with the construction project; and
transmitting, based on the development status, a closeout package associated with the construction project.

8. The non-transitory computer-readable medium of claim 7, wherein the multi-dimensional model comprises at least one layer comprising at least one of: an energy layer, a public utility layer, a parcel layer, or a zoning layer, wherein the at least one layer is generated based on the metadata.

9. The non-transitory computer-readable medium of claim 7, wherein the instructions, when executed, further cause:
receiving a plurality of images associated with the area of interest; and
generating, based on the plurality of images, an orthomosaic image associated with another subset of the area of interest, wherein the multi-dimensional model is further based on the orthomosaic image.

10. The non-transitory computer-readable medium of claim 7, wherein the second data source comprises a geographical information system (GIS) database and the metadata comprises at least one of transportation information, building data, vegetation data, boundary data, or elevation data.

11. (canceled)

12. A method performed by one or more computing devices, the method comprising:
receiving, from at least one sensor associated with a first data source, first capture data associated with a first fixture, wherein the first fixture is associated with a construction project within an area of interest;
receiving, from the at least one sensor associated with the first data source, second capture data associated with a second fixture, wherein the second fixture is associated with the construction project within the area of interest;
determining, based on the first capture data, a plurality of first characteristics associated with the first fixture;
determining, based on the second capture data, a plurality of second characteristics associated with the second fixture;
receiving, from a second data source, metadata associated with a subset of the area of interest;
generating, based on the plurality of first characteristics and the plurality of second characteristics, a multi-dimensional model associated with the area of interest;
determining, based on the metadata, at least one development status associated with the construction project; and
transmitting, based on the development status, a closeout package associated with the construction project.

13. The method of claim 12, further comprising:
generating a plurality of normalized tracking objects based on the plurality of first characteristics, the plurality of second characteristics, and the metadata; and
storing, in a data store, the plurality of normalized tracking objects.

14. The method of claim 12, further comprising:
determining a current position and an orientation associated with a mobile computing device;
determining positional information corresponding to a captured area from a camera feed of the mobile computing device;
determining, based on the positional information and the multi-dimensional model, the captured area is associated with the first fixture; and
rendering, on a display, the camera feed and an overlaid indicator at a position within the captured area.

15. (canceled)

16. The method of claim 12, wherein determining the plurality of first characteristics for the first fixture comprises:
capturing, via the at least one sensor, an image associated with the first fixture;
determining, when the image is captured, a first coordinate and an orientation associated with the at least one sensor;
identifying the first fixture in the image; and
determining a second coordinate associated with the first fixture based on the identification of the first fixture in the image, the first coordinate, and the orientation, wherein the plurality of first characteristics comprises the first coordinate.

17. The method of claim 16, wherein determining the plurality of first characteristics comprises:
determining at least one point associated with the first fixture; and
determining at least one vertical position associated with the at least one point, wherein the plurality of first characteristics comprises the at least one vertical position.

18. The method of claim 12, wherein the second data source comprises permit data and the at least one development status comprises a permit status for a respective one of a plurality of project components.

19. The method of claim 12, further comprising:
generating an invoice for at least one of a plurality of project components, wherein the second data source comprises accounting data; and
transmitting the invoice for the at least one of the plurality of project components to a user account associated with the at least one of the plurality of project components.

20. The method of claim 12, further comprising:
receiving a request for a report corresponding to the area of interest;
generating the report based on the multi-dimensional model; and
transmitting the report based on the request.

21. The system of claim 1, wherein the development status comprises one or more of a current progress, an expected time of completion, a current cost of construction, or a total budget.

22. The non-transitory computer-readable medium of claim 7, wherein the development status comprises one or more of a current progress, an expected time of completion, a current cost of construction, or a total budget.

23. The method of claim 12, wherein the development status comprises one or more of a current progress, an expected time of completion, a current cost of construction, or a total budget.
